(19) United States
(12) Patent Application Publication
(10) Pub. No.: US 2024/0072025 A1
(43) Pub. Date: Feb. 29, 2024

(54) Tunable Fingertip Capacitors with Enhanced Shielding in Ceramic Package

(71) Applicant: Texas Instruments Incorporated, Dallas, TX (US)

(72) Inventors: Rajen M. Murugan, Dallas, TX (US); Yiqi Tang, Allen, TX (US); Jie Chen, Plano, TX (US); Ramlah Abdul Razak, Plano, TX (US)

(21) Appl. No.: 17/893,312

(22) Filed: Aug. 23, 2022

(51) Int. Cl. H01L 25/16; H01L 23/00; H01L 23/367; H01L 23/552

(52) U.S. Cl. CPC H01L 25/165; H01L 23/3675; H01L 23/552; H01L 24/32; H01L 24/48; H01L 24/73; H01L 2224/32245; H01L 2224/48195; H01L 2224/73265; H01L 2924/16195; H01L 2924/16251; H01L 2924/1632; H01L 2924/17787; H01L 2924/19041; H01L 2924/30105; H01L 2924/3025

(57) ABSTRACT

An example semiconductor package comprises a ceramic header having a first open space separated from a second open space by a ceramic barrier. A first heat sink is attached to a bottom of the ceramic header below the first open area. A first integrated circuit (IC) die is mounted on the first heat sink. A second heat sink is attached to a bottom of the ceramic header below the second open area. A second IC die is mounted on the second heat sink. A capacitive interface is disposed in the ceramic barrier between the first IC die and the second IC die. The capacitive has a plurality of capacitive elements alternating with a plurality of shielding elements. The capacitive elements are tunable over a range of capacitive values.

### BACKGROUND

Ceramic hermetic packages are often used in military and space applications for sensitive parts that have a need for physical and atmospheric protection. Sensitive devices can be surrounded by a housing or package that shields the device against ambient and electrical disturbances and against stress. Galvanic isolation prevents current flow between the functional sections of electrical systems. To prevent current flow, no direct conduction path is permitted. Energy or information can still be exchanged between the sections by other means, such as capacitance, induction, or electromagnetic waves, or by optical, acoustic, or mechanical means.

Galvanic isolation may be used where two or more electric circuits must communicate, but their grounds may be at different potentials. Integrated, capacitive-based, galvanic isolators allow information to be transmitted between nodes of a system at different voltage levels using a capacitive barrier.

### SUMMARY

In an arrangement, a semiconductor package comprises a ceramic header having two interior cavities separated by a ceramic barrier. A semiconductor die is mounted within each of the cavities. A capacitive interface is formed within the ceramic barrier between the semiconductor dies and provides a communication path between the semiconductor dies mounted within each of the cavities. The capacitive interface has a plurality of capacitive elements alternating with a plurality of shielding elements. A lid structure is coupled to a top surface of the ceramic header. The lid structure and ceramic header forming a hermetic portion of a package enclosing the semiconductor dies. A first heat sink is coupled to a bottom surface of the ceramic header and provides a mounting surface for a first semiconductor die. A second heat sink is coupled to the bottom surface of the ceramic header and provides a mounting surface for a second semiconductor die. The first and second heat sink provide independent ground planes for the first and second semiconductor dies. The capacitive elements are tunable over a range of capacitive values.

The capacitive elements in the capacitive interface comprise a first upper segment adjacent to a first semiconductor die, a second upper segment adjacent to a second semiconductor die, and a central lower segment extending from the first upper segment and the second upper segment. The central lower segment extends under, but is not attached to, the first upper segment. The central lower segment is conductively attached to the second upper segment. The central lower segment is conductively attached to the second upper segment by a conductive via through the ceramic barrier. The capacitance value of the capacitive elements is determined by an amount of overlap between the first upper segment and the lower central segment. In some arrangements, the capacitance values of each capacitive element are approximately 60 fF.

The shielding elements in the capacitive interface comprise a first upper segment adjacent to a first semiconductor die, a second upper segment adjacent to a second semiconductor die, a first lower segment positioned below and conductively attached to the first upper segment, the first lower segment conductively attached to a first heat sink, and a second lower segment positioned below and conductively attached to the second upper segment. The second lower segment is conductively attached to a second heat sink, The first lower segment and the second lower segment extend toward each other but do not touch. An end of the first lower segment is adjacent an edge of the first heat sink, and an end of the second lower segment is adjacent an edge of the second heat sink. The first lower segment is conductively attached to the first upper segment and to the first heat sink by conductive vias through the ceramic barrier, and the second lower segment is conductively attached to the second upper segment and to the second heat sink by conductive vias through the ceramic barrier. The shielding elements in the capacitive interface provides ground shielding between adjacent ones of the capacitive elements.

The shielding elements in the capacitive interface comprise a first lower segment and a second lower segment spaced apart from the first lower segment. A distance between the first lower segment and the second lower segment provides electrical isolation between a first semiconductor die and a second semiconductor die.

In another arrangement, a system comprises a ceramic header having a first open space separated from a second open space by a ceramic barrier, a first heat sink attached to a bottom of the ceramic header below the first open area, a first IC die mounted on the first heat sink, a second heat sink attached to a bottom of the ceramic header below the second open area, a second IC die mounted on the second heat sink, and a capacitive interface in the ceramic barrier between the first IC die and the second IC die. The capacitive interface having a plurality of capacitive elements alternating with a plurality of shielding elements. A first set of bond wires couples the first IC die to first ends of the capacitive elements, and a second set of bond wires coupling the second IC die to second ends of the capacitive elements. A lid structure is coupled to a top surface of the ceramic header, the lid structure and ceramic header forming a portion of a package enclosing the semiconductor dies.

The capacitive elements comprise a first upper segment adjacent to the first IC die, a second upper segment adjacent to the second IC die, and a central lower segment extending from the first upper segment to the second upper segment. The central lower segment extends under but is not attached to the first upper segment. The central lower segment is conductively attached to the second upper segment by a conductive via through the ceramic barrier. The capacitance value of the capacitive elements is determined by an amount of overlap between the first upper segment and the lower central segment.

The shielding elements comprise a first upper segment adjacent to a first semiconductor die, a second upper segment adjacent to a second semiconductor die, a first lower segment positioned below and conductively attached to the first upper segment by one or more conductive vias through the ceramic barrier, and a second lower segment positioned below and conductively attached to the second upper segment. The first lower segment is conductively attached to the first heat sink, and the second lower segment conductively attached to the second heat sink by one or more conductive vias conductive via through the ceramic barrier. The first lower segment and the second lower segment extend toward each other but do not touch. An end of the first lower segment is adjacent an edge of the first heat sink, and an end of the second lower segment is adjacent an edge of the second heat sink. The shielding elements in the capacitive interface provide ground shielding between adjacent ones of the capacitive elements.

### BRIEF DESCRIPTION OF THE DRAWINGS

Having thus described the invention in general terms, reference will now be made to the accompanying drawings, wherein:

FIG. 1 is a top perspective view of a ceramic multi-chip module dual-cavity package.

FIG. 2 is a detailed view of a capacitive interface between the IC dies in the MCM dual-cavity package of FIG. 1.

FIG. 3 is a cross section view of the ceramic MCM dual-cavity package shown in FIG. 1 taken through a first capacitive element.

FIG. 4 is a cross section view of the ceramic MCM dual-cavity package shown in FIG. 1 taken through a second capacitive element.

FIG. 5 is a cross section view of the ceramic MCM dual-cavity package shown in FIG. 1 taken through a shielding element.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “ceramic header” is used herein. A ceramic header in a completed semiconductor device package includes a mounting portion configured to provide a mounting surface for an electronic device. Ceramic headers useful with the arrangements can be formed from aluminum oxide or aluminum nitride. The ceramic header can include a bond pad surface for mounting a semiconductor die. Conductive leads couple bond pads on the semiconductor die to contacts on the outside surface of the ceramic header. More than one semiconductor die can be mounted to ceramic header.

The term “capacitive interface” is used herein. A capacitive interface in a semiconductor device package or multi-chip module provides a connection between two systems or devices, such as semiconductor dies. The capacitive interface allows the two systems or devices to be capacitively coupled so that signals may pass between the systems or devices but does not provide direct conductive connection between the systems or devices. This allows the systems or devices to have separate and independent ground potentials and voltage domains.

The term “capacitive element” is used herein. A capacitive element in a capacitive interface provides capacitive coupling between two systems or devices. The capacitive element creates capacitance through the interaction of overlapping parallel plates. The capacitive elements may be formed in a ceramic substrate such as by screen printing conductive traces between layers of a ceramic dielectric. The conductive traces may be formed using copper (Cu), tungsten (W), or other metal or a conductive alloy. In one example, the conductive traces have a width from 0.08 um to 0.15 um. Capacitance may be adjusted by changing the length of overlapping conductive traces. In one example, the overlapping length of conductive traces may vary from 10 um to 1 mm to create a capacitance of 20 fF to 180 fF. A gap between the overlapping conductive traces may vary between 0.3 mm to 0.9 mm in one arrangement.

The term “shielding element” is used herein. A shielding element in a capacitive interface provides isolation between two systems or devices, such as semiconductor devices or capacitive elements. The shielding element is coupled to a ground plane and reduces radiation of adjacent capacitive elements. The shielding elements may be formed in a ceramic substrate such as by screen printing conductive traces between layers of a ceramic dielectric. The conductive traces may be coupled to each other and to the ground plane by conductive vias in the ceramic substrate.

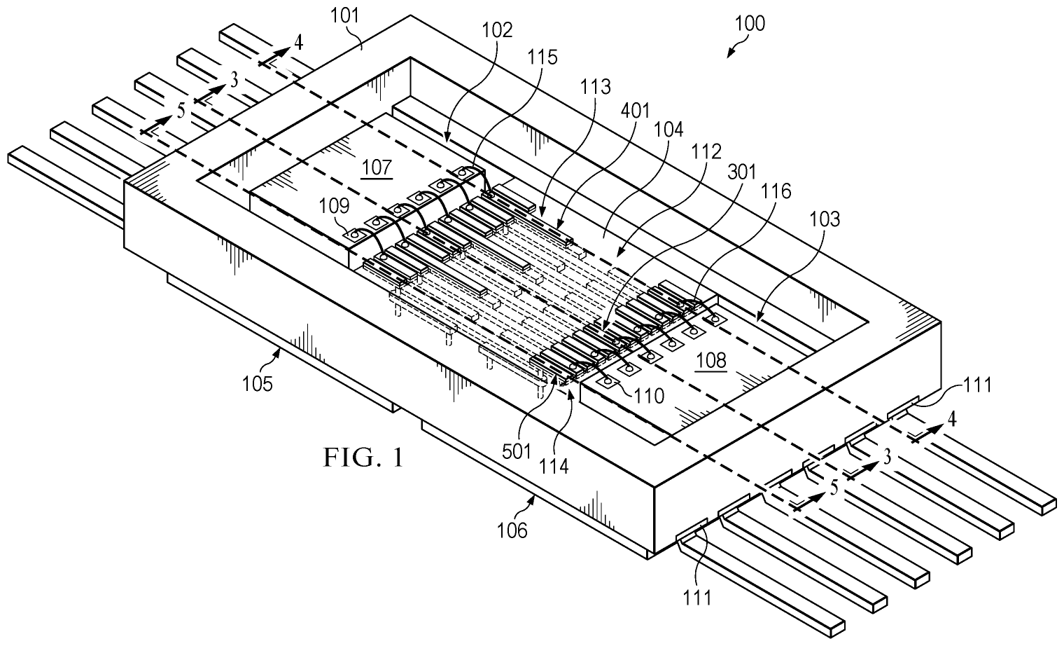

FIG. 1 is a top perspective view of a ceramic multi-chip module (MCM) dual-cavity package 100. A ceramic header 101 is formed to create two open interior cavities or spaces 102, 103 that are separated by a ceramic barrier 104 that is part of ceramic header 101. Heat sinks 105, 106 are attached to the bottom of cavities 102, 103, respectively, to dissipate heat from package 100. Heat sinks 105, 106 also function as an interior mounting surface for semiconductor devices, such as an integrated circuit (IC) dies 107, 108. In the illustrated example, ceramic header 101 forms at least a portion of a hermetic seal. Ceramic header 101 may comprise any suitable ceramic material used in electronic device packaging, such as Alumina (Al₂O₃), Aluminum Nitride (AlN), or Low Temperature Co-fired Ceramics (LTCC). Ceramic header 101 may be a multi-layer substrate having metallized or conductive traces (not shown) within the layers. These conductive traces may be used to couple conductive pads 111 on the exterior of header 101 to bond pads 109, 110 on IC dies 107, 109. Heat sinks 105, 106 may comprise, for example, a highly conductive metal, such as copper-tungsten (CuW). Dies 105, 106 may be attached to heat sinks 105, 106 using a die attach film, paste, or solder or silver glass.

Ceramic barrier 104 has an interface 112 including a plurality of metal traces that extend laterally between interior cavities 102, 103 and IC dies 107, 108. The interface 112 includes a number of capacitive elements 113 alternating with shielding elements 114. The capacitive elements 113 provide communication and isolation between IC dies 107, 108. The capacitive elements 113 may be coupled to bond pads 109 on IC die 107 via bond wires 115 and to bond pads 110 on IC die 108 via bond wires 116.

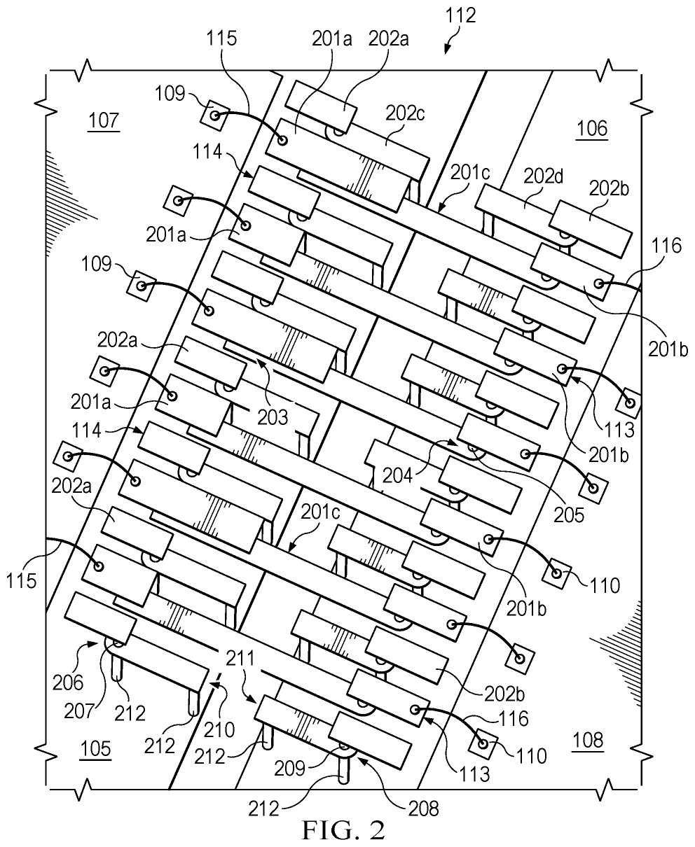

FIG. 2 is a detailed view of the interface 112 between IC dies 107, 108 in MCM dual-cavity package 100. Each capacitive element 113 has three components, including a first upper segment 201a, second upper segment 201b, and central lower segment 201c. The first upper segment 201a and the second upper segment 201b on each capacitive element 113 are exposed on the top and/or side of ceramic barrier 104 (not shown in FIG. 2 for clarity of the illustration). The first upper segments 201a for each capacitive element 113 may be coupled to bond pads 109 on IC die 107 via bond wires 115. The second upper segments 201b may be coupled to bond pads 110 on IC die 108 via bond wires 116.

The central lower segments 201c of each capacitive element 113 are embedded in ceramic barrier 104. The central lower segments 201c are elongated metal strips extending between a first end 203 and a second end 204. In one arrangement, the second end 204 of each central lower segment 201c is directly attached to a respective second upper segment 201b. This connection may be made by a via 205 drilled in ceramic barrier 104 and filled with a conductive material such as molybdenum (Mo). In this arrangement, the first end 203 of each central lower segment 201c extends below a respective first upper segment 201a; however, the first end 203 is not directly attached to the first upper segment 201a.

The central lower segment 201c and a respective first upper segment 201a for each capacitive element 113 are coupled by a parallel plate capacitive effect. The value of the capacitance can be selected by varying the amount of overlap between the central lower segment 201c and the respective first upper segment 201a. In one arrangement, the lengths of each of the central lower segments 201c are generally the same. The lengths of each first upper segment 201a may be different so that each capacitive element 113 has a different capacitance that is caused by varying degrees of overlap between elements 201a and 201c. This arrangement provides a number of channels between IC dies 107 and 108 corresponding to the number of capacitive elements 113. In one configuration, the number of capacitive elements 113 is six, which provides six channels between IC dies 107 and 108.

The lengths of each first upper segment 201a are selectable for a particular ceramic MCM dual-cavity package 100 design, which allows the interface 112 to be tuned by a designer. This allows a designer to configure a desired level of communication and isolation between IC dies 107 and 108. In one arrangement, the first upper segments 201a are referred to as “fingertips,” and the capacitive elements 201 as a whole may be referred to as “fingertip capacitors (FTC).”

Each shielding element 114 has four components, including a first upper segment 202a, second upper segment 202b, first lower segment 202c, and second lower segment 202d. The first upper segment 202a and the second upper segment 202b for each shielding element 114 are exposed on the top and/or side of ceramic barrier 104. The first and second lower segments 202c, 202d for each capacitive element 114 are embedded in ceramic barrier 104. The first and second lower segments 202c, 202d are elongated metal strips. In one arrangement, one end 206 of each first lower segment 202c is directly attached to a respective first upper segment 202a, such as by a via 207 drilled in ceramic barrier and filled with a conductive material such as molybdenum (Mo). Similarly, one end 208 of each second lower segment 202d is directly attached to a respective second upper segment 202b, such as by conductive material in a via 209 drilled in ceramic barrier. The unattached ends 210, 211 of the first and second lower segments 202c, 202d, respectively, are spaced apart so that there is no direct physical connection between the lower segments 202c and 202d.

The shielding elements 114 are directly connected to a ground plane, such as heat sink 105 or 106. For example, each of the lower segments 202c and 202d may be coupled by one or more vias 212 to heat sink 105 or 106. The shielding elements 114 provide additional control of the isolation, parasitic, and resonance parameters of interface 112. The use of capacitive elements 113 and shielding elements 114 provides a stable capacitance across a desired frequency range with minimal parasitic resistance and inductance, minimal system level resonance, and no compromise to isolation between IC dies 107 and 108.

In one arrangement, ceramic MCM dual-cavity package 100 may be used in a system wherein IC dies 107 and 108 must communicate with each other, but their grounds are at different potentials. Interface 112 provides isolating functionality to the IC dies 107 and 108 to prevent current flow from one device to another. Integrated, capacitive-based interface 112 allows information to be transmitted between nodes of a system at different voltage levels using a capacitive barrier. In one arrangement, IC dies 107 and 108 may be power metal-oxide-semiconductor field-effect transistors (MOSFETs) that are coupled together by interface 112, wherein one IC die 108 is a high-side device and the other IC die 107 is a low side device with a different ground potential.

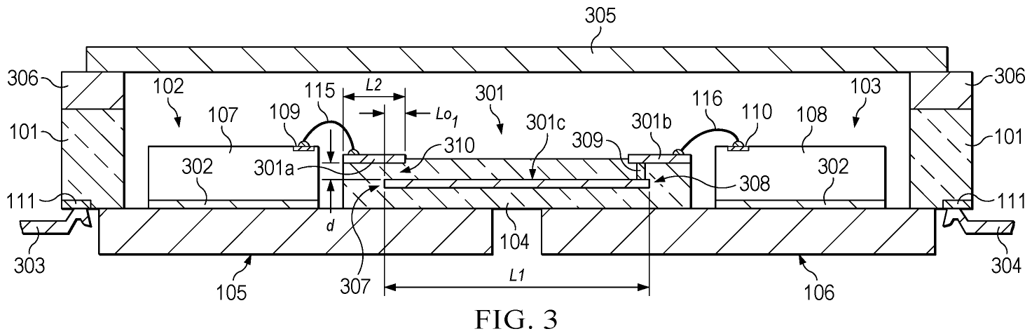

FIG. 3 is a cross section view of ceramic MCM dual-cavity package 100 shown in FIG. 1 taken through a first capacitive element 301. Ceramic header 101 is formed to create the interior cavities 102, 103 separated by ceramic barrier 104. Heat sinks 105, 106 are attached to the bottom of cavities 102, 103, respectively, to dissipate heat from package 100. Heat sinks 105, 106 also function as an interior mounting surface for semiconductor devices, such as an integrated circuit (IC) dies 107, 108, and provide a separate ground plane for each device. IC dies 107 and 108 are mounted to heat sinks 105 and 106, respectively, using a die attach film, paste, or solder or silver glass 302. Capacitive element 301 provide communication and isolation between IC dies 107, 108. The capacitive element 301 is coupled to bond pad 109 on IC die 107 via bond wire 115 and to bond pad 110 on IC die 108 via bond wire 116. Conductive traces (not shown) within layers of ceramic header 101 may be used to couple conductive pads 111 on the exterior of header 101 to bond pads 109, 110 on IC dies 107, 108. Leads 303, 304 may be attached to conductive pads 111 to connect ceramic MCM dual-cavity package 100 to external circuits and systems.

The open interior cavities 102, 103 of ceramic header 101 are sealed using a lid 305 that is attached to ceramic header 101 with a seal ring. The material forming lid 305 may be a moisture-impenetrable material such as glass, ceramic, or metal to provide a fully hermetic sealing over ceramic header 101. Seal ring 306 may be, for example, Kovar metal or alloy metallization and plated with a Nickel-Gold (NiAu) alloy, such as a lid with solder preform comprising 80% gold and 20% tin. The interior cavities 102 and 103 may be hermetically sealed when the lid 305 is attached by an airtight and watertight seal to ceramic header 101.

Capacitive element 301 has three main components, including first upper segment 301a, second upper segment 301b, and central lower segment 301c. The first upper segment 301a and the second upper segment 301b are exposed on the top and/or side of ceramic barrier 104, which allows attachment of bond wires 115, 116. Central lower segment 301c is embedded in ceramic barrier 104. The first upper segment 301a, second upper segment 301b, and central lower segment 301c are constructed from a conductive material, such as copper (Cu), tungsten (W), a copper-tungsten (Cu—W) alloy, molybdenum (Mo), or other metal or alloy.

Central lower segment 301c has a first end 307 and a second end 308. The first end 307 extends below a portion of first upper segment 301a. The central lower segment 301c is not directly attached to the first upper segment 301a; however, first upper segment 301a and the central lower segment 301c may be capacitively coupled. The second end 308 is directly attached to the second upper segment 301b by a via 309. In one configuration, via 309 is drilled in ceramic barrier 104 and filled with a conductive material such as molybdenum (Mo).

As noted in relation to FIG. 2 above, in one arrangement, the length the central lower segment 201c for each capacitive element 113 in interface 112 may be of a fixed length and the length of the first upper segment 201a is selected by a designer to achieve a desired capacitance. As shown in FIG. 3, the central lower segment 301c has a length L1, and the first upper segment 301a has a length L2. Length of the overlapping portion 310 is Lo₁. In some configurations, the length L1 of central lower segment 301c may be the same for all of the capacitive elements 113, and the length L2 of first upper segment 301a (the “fingertip” portion) may be varied for each capacitive element 113 to achieve a different capacitance. In other configurations, the length L1 of central lower segment 301c may be varied for each capacitive element 113, and the length L2 of first upper segment 301a may be the same for each capacitive element 113 to achieve different capacitance values.

The value of capacitance for element 301 can be determined using the equation: C=(ε₀·A)/d, where C is capacitance, ε₀ is the dielectric constant, A is the area of the overlapping portion of the segments, and d is the distance between the segments. Assuming that the central lower segment 301c and the first upper segment 301a have the same width W, then the area A₁ in element 301 is equal to W·Lo₁. Therefore, by varying the length of the fingertip portions 301a, the parallel plate capacitance C₁ for element 301 can be set to a desired value (where, C₁=(ε₀·A₁)/d). In one arrangement, by varying the fingertip length L2, which in turn varies overlapping length Lo₁, a designer can tune isolation capacitance values for each element 301, which allows interface 112 to fit multiple applications requiring different capacitance values. For ceramic materials forming header 101, use of a high dielectric constant (D k) material ensures that the capacitance values can be repeated with good frequency response.

The capacitive elements are tunable over a range of capacitive values. In one configuration, six capacitive elements 301 are used for an interface 112 and the first upper segments 301a are selected to provide 60 fF capacitance. In another example configuration, the width of the capacitive elements is selected from or between 0.08 um and 0.15 um. The overlapping length Lo₁ between a first upper segment 301a and a central lower segment 301c may be varied between 10 um to 1 mm to achieve a capacitance range of 20 fF to 180 fF. The distance between the overlapping segments may be selected from 0.3 mm to 0.9 mm in one arrangement. The tunable capacitance can be used in multiple devices and applications and saves expensive chip area by eliminating discrete components. Each capacitive element may be tuned to a different capacitive value or all may be tuned to the same value.

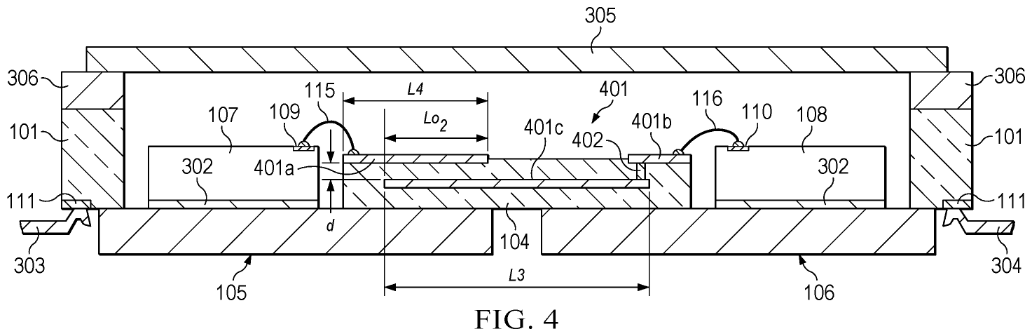

FIG. 4 is a cross section view of ceramic MCM dual-cavity package 100 shown in FIG. 1 taken through a second capacitive element 401. Like capacitive element 301 (FIG. 3), capacitive element 401 has three main components, including first upper segment 401a, second upper segment 401b, and central lower segment 401c. The first upper segment 401a and the second upper segment 401b are exposed on the top and/or side of ceramic barrier 104, which allows attachment of bond wires to IC dies 107 and 108, respectively. The central lower segment 401c is embedded in ceramic barrier 104 and is directly coupled to second upper segment 401b using via 402.

The separation between central lower segment 401c and the upper segments 401a, 401b is the same distance d as the separation in capacitive element 301. Also, central lower segment 401c and the upper segments 401a, 401b have the same width W as the segments in capacitive element 301. Generally, the length L3 of central lower segment 401c is the same as the length L1 of central lower segment 301c. However, because the length L4 of first upper segment 401a is longer than the length L2 of first upper segment 301a, the overlapping length Lo₂ in capacitive element 401 is longer than overlapping length Lo₁ in element 301. This longer overlap results in a correspondingly larger area A₂ in element 401 equal to W·Lo₂, which in turn results in a larger capacitance C₂ in element 401 compared to element 301 (where, C₂=(ε₀·A₂)/d).

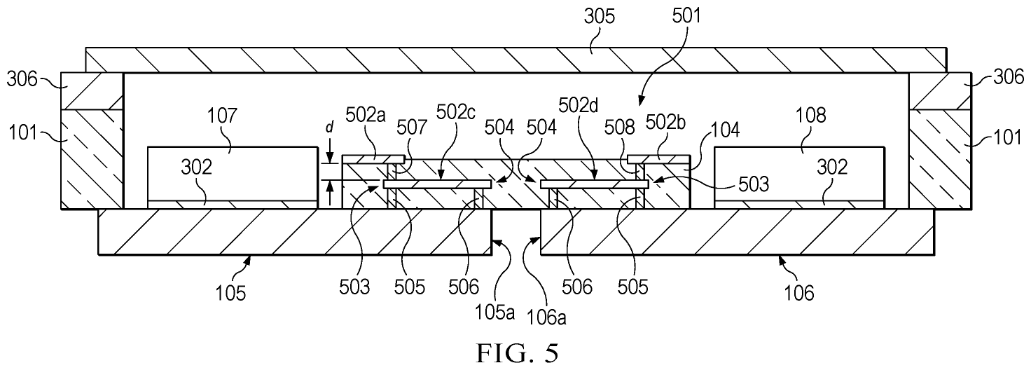

FIG. 5 is a cross section view of ceramic MCM dual-cavity package 100 shown in FIG. 1 taken through a shielding element 501. The shielding element 501 has four components, including a first upper segment 502a, second upper segment 502b, first lower segment 502c, and second lower segment 502d. The first upper segment 502a and the second upper segment 502b for each shielding element 501 are exposed on the top and/or side of ceramic barrier 104. The first and second lower segments 502c, 502d for each capacitive element 501 are embedded in ceramic barrier 104. In one configuration, the first and second lower segments 502c, 502d are separated from upper segments 502a, 502b by a distance d similar to capacitive elements 301 and 401.

The lower segments 502c and 502d each extend from a first end 503 near the respective IC dies 107 and 108 to a second end 504 near an edge 105a, 106a of respective heat sinks 105, 106. The lower segments 502c and 502d are each attached to the respective heat sink 105, 106 by vias 505, 506, which are conductive paths through ceramic barrier material 104. Upper segment 502a is attached to lower segment 502c by a conductive via 507, and upper segment 502b is attached to lower segment 502d by a conductive via 508.

The unattached ends 504 of the first and second lower segments 502c, 502d are spaced apart so that there is no direct physical connection between the lower segments 502c and 502d. Although shown as ending at the edges 105a, 106a of the heat sinks 105, 106, in other arrangements, the ends 504 of lower segments 502c and 502d may be positioned away from the edges 105a, 106a. The lack of physical contact between the first upper and lower segments 502a. 502c and the second upper and lower segments 502b, 502d provides isolation between the ground plane of heat sinks 105 and 106 and eliminates coupling between the two sides of ceramic MCM dual-cavity package 100. Shielding element 501 and similar elements 114 that are positioned between the capacitive elements 113 reduce radiation among the elements and improve isolation between IC dies 107 and 108.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a ceramic header having two interior cavities separated by a ceramic barrier;
semiconductor dies mounted within each of the cavities; and
a capacitive interface formed within the ceramic barrier and providing a communication path between the semiconductor dies, the capacitive interface having a plurality of capacitive elements alternating with a plurality of shielding elements.

2. The semiconductor package of claim 1, further comprising:
a lid structure coupled to a top surface of the ceramic header, the lid structure and ceramic header forming a portion of a package enclosing the semiconductor dies;
a first heat sink coupled to a bottom surface of the ceramic header and providing a mounting surface for a first semiconductor die; and
a second heat sink coupled to the bottom surface of the ceramic header and providing a mounting surface for a second semiconductor die, wherein the first and second heat sink provide independent ground planes for the first and second semiconductor dies.

3. The semiconductor package of claim 1, wherein the capacitive elements in the capacitive interface comprise:
a first upper segment adjacent to a first semiconductor die;
a second upper segment adjacent to a second semiconductor die; and
a central lower segment extending from the first upper segment and the second upper segment.

4. The semiconductor package of claim 3, wherein the central lower segment extends under but is not attached to the first upper segment; and the central lower segment is conductively attached to the second upper segment.

5. The semiconductor package of claim 4, wherein the central lower segment is conductively attached to the second upper segment by a conductive via through the ceramic barrier.

6. The semiconductor package of claim 4, wherein a capacitance value of the capacitive elements is determined by an amount of overlap between the first upper segment and the lower central segment.

7. The semiconductor package of claim 1, wherein capacitance values of each capacitive element are approximately the same.

8. The semiconductor package of claim 1, wherein capacitance values of each capacitive element is different.

9. The semiconductor package of claim 1, wherein the shielding elements in the capacitive interface comprise:
a first upper segment adjacent to a first semiconductor die;
a second upper segment adjacent to a second semiconductor die;
a first lower segment positioned below and conductively attached to the first upper segment, the first lower segment conductively attached to a first heat sink; and
a second lower segment positioned below and conductively attached to the second upper segment, the second lower segment conductively attached to a second heat sink, wherein the first lower segment and the second lower segment extend toward each other but do not touch.

10. The semiconductor package of claim 9, wherein an end of the first lower segment is adjacent an edge of the first heat sink, and wherein an end of the second lower segment is adjacent an edge of the second heat sink.

11. The semiconductor package of claim 9, wherein the first lower segment is conductively attached to the first upper segment and to the first heat sink by conductive vias through the ceramic barrier.

12. The semiconductor package of claim 11, wherein the second lower segment is conductively attached to the second upper segment and to the second heat sink by conductive vias through the ceramic barrier.

13. The semiconductor package of claim 1, wherein the shielding elements in the capacitive interface provide ground shielding between adjacent ones of the capacitive elements.

14. The semiconductor package of claim 1, wherein the shielding elements in the capacitive interface comprise:
a first lower segment; and
a second lower segment spaced apart from the first lower segment, wherein a distance between the first lower segment and the second lower segment provides electrical isolation between a first semiconductor die and a second semiconductor die.

15. A system, comprising:
a ceramic header having a first open space separated from a second open space by a ceramic barrier;
a first heat sink attached to a bottom of the ceramic header below the first open space;
a first integrated circuit (IC) die mounted on the first heat sink;
a second heat sink attached to a bottom of the ceramic header below the second open space;
a second IC die mounted on the second heat sink; and
a capacitive interface in the ceramic barrier between the first IC die and the second IC die, the capacitive interface having a plurality of capacitive elements alternating with a plurality of shielding elements.

16. The system of claim 15, further comprising:
a first set of bond wires coupling the first IC die to first ends of the capacitive elements;
a second set of bond wires coupling the second IC die to second ends of the capacitive elements; and
a lid structure coupled to a top surface of the ceramic header, the lid structure and ceramic header forming a portion of a package enclosing the IC dies.

17. The system of claim 15, wherein the capacitive elements comprise:
a first upper segment adjacent to the first IC die;
a second upper segment adjacent to the second IC die; and
a central lower segment extending from the first upper segment to the second upper segment, wherein the central lower segment extends under but is not attached to the first upper segment; and the central lower segment is conductively attached to the second upper segment by a conductive via through the ceramic barrier.

18. The system of claim 17, wherein a capacitance value of the capacitive elements is determined by an amount of overlap between the first upper segment and the lower central segment.

19. The system of claim 15, wherein the shielding elements comprise:
a first upper segment adjacent to a first semiconductor die;
a second upper segment adjacent to a second semiconductor die;
a first lower segment positioned below and conductively attached to the first upper segment by one or more conductive vias through the ceramic barrier, the first lower segment conductively attached to the first heat sink; and
a second lower segment positioned below and conductively attached to the second upper segment, the second lower segment conductively attached to the second heat sink by one or more conductive vias conductive via through the ceramic barrier, wherein the first lower segment and the second lower segment extend toward each other but do not touch.

20. The system of claim 19, wherein an end of the first lower segment is adjacent an edge of the first heat sink, and wherein an end of the second lower segment is adjacent an edge of the second heat sink, and wherein the shielding elements in the capacitive interface provide ground shielding between adjacent ones of the capacitive elements.
